(19) United States
(12) Patent Application Publication
(10) Pub. No.: US 2014/0151714 A1
(43) Pub. Date: Jun. 5, 2014

(54) GALLIUM NITRIDE SUBSTRATE AND METHOD FOR FABRICATING THE SAME

(71) Applicant: SEOUL VIOSYS CO., LTD., Ansan-si (KR)

(72) Inventors: Ki Yon PARK, Ansan-si (KR); Hwa Mok Kim, Ansan-si (KR); Daewoong Suh, Ansan-si (KR); Young Hwan Son, Ansan-si (KR)

(73) Assignee: SEOUL VIOSYS CO., LTD., Ansan-si (KR)

(21) Appl. No.: 14/096,189

(22) Filed: Dec. 4, 2013

(30) Foreign Application Priority Data
Dec. 4, 2012 (KR) 10-2012-0139784

(51) Int. Cl. H01L 33/32; H01L 33/12; H01L 33/00

(52) U.S. Cl. CPC H01L 33/32; H01L 33/0075; H01L 33/12
USPC 257/76; 438/507

(57) ABSTRACT

Exemplary embodiments of the present invention relate to a single-crystal substrate including a buffer layer including a nitride semiconductor, holes penetrating the buffer layer, and a single-crystal nitride semiconductor disposed on the buffer layer.

### CROSS-REFERENCE TO RELATED APPLICATION

This application claims priority from and the benefit of Korean Patent Application No. 10-2012-0139784, filed on Dec. 4, 2012, which is incorporated herein by reference for all purposes as if fully set forth herein.

### BACKGROUND

1. Field

Exemplary embodiments of the present invention relate to a single-crystal gallium nitride (GaN) substrate and a method for fabricating the same. Particularly, exemplary embodiments of the present invention relate to a single-crystal GaN substrate in which holes are formed in a heterogeneous growth substrate in order to prevent cracking and to permit the heterogeneous growth substrate to be easily separated, and a method for fabricating the same.

2. Discussion of the Background

A light-emitting diode (LED) may be a light-emitting semiconductor that converts energy, generated by the combination of electrons and holes, into light energy. The LED may be an element having high-response speed, and so on. Such an LED may formed through an epitaxial growth process, then chip fabrication process, packaging process, and module formation. Among these processes, the epitaxial growth process may be considered to be a basic process of the LED formation.

The epitaxial growth process may include growing a semiconductor thin film having an LED structure (i.e., a p-n junction structure) on a substrate, such as sapphire, SiC, or silicon (Si). The epitaxial growth process may fundamentally determine LED performance through thin film quality, including defects, an interface, and doping in the structure.

GaN may be used as a semiconductor material for a thin film formed on the substrate. GaN has an energy bandgap of 3.4 eV and a direct shift type and that may be useful in fabricating an LED. GaN may be used in ultraviolet, blue, green, and white light emitting LEDs, laser diodes, ultraviolet photodetectors, and high-speed electronic devices.

Laser Lift-Off (LLO) may be used in a process of separating an epitaxially grown GaN thin film from a heterogeneous growth substrate. If a porous pattern in the heterogeneous growth substrate has low uniformity, strain may be locally concentrated, which may weaken the GaN thin film during the separation process, thereby generating a crack in the heterogeneous substrate and the GaN thin film grown thereon. Thus, it may be difficult to implement a high-quality and single-crystal GaN-based substrate.

The above information disclosed in this Background section is only for enhancement of understanding of the background of the invention and therefore it may contain information that does not form any part of the prior art nor what the prior art may suggest to a person of ordinary skill in the art.

### SUMMARY OF THE INVENTION

Exemplary embodiments of the present invention provide a single-crystal GaN substrate using an epitaxial growth heterogeneous substrate having a structure capable of preventing a crack occurring due to strain.

An exemplary embodiment of the present invention also provides a method for fabricating a single-crystal nitride substrate using an epitaxial growth heterogeneous substrate capable of reducing a crack occurring due to strain, permitting the heterogeneous substrate to be easily separated, and improving the yield of the single-crystal substrate.

Other objects and advantages of the present invention can be understood by the following description, and become apparent with reference to the exemplary embodiments of the present invention. Also, it is obvious to those skilled in the art to which the present invention pertains that the objects and advantages of the present invention can be realized by the means as claimed and combinations thereof.

An exemplary embodiment of the present invention discloses a single-crystal GaN substrate including a buffer layer including a nitride semiconductor, holes penetrating the buffer layer, and a single-crystal nitride semiconductor disposed on the buffer layer.

The buffer layer includes a first layer disposed on the substrate, to the first layer including AlN, a second layer disposed on the first layer, the second layer including AlₓGa₁₋ₓN, wherein 0<x<1, and a third layer disposed on the second layer, the third layer including GaN.

The single-crystal GaN substrate further includes a substrate, wherein the buffer layer is disposed on the substrate, and the holes extend into the substrate.

Each of the holes includes a hole region penetrating the buffer layer and an undercut region extending from the hole region and etching part of the substrate, and the undercut region has a larger diameter than the hole region.

The second layer includes gradually reduced ‘x’ in AlₓGa₁₋ₓN in a direction extending away from the first layer.

The second layer includes layers having different Al compositions and a gradually reduced composition of ‘x’ in a direction extending away from the first layer.

The holes have uniform diameters and intervals therebetween.

An interval between adjacent holes may is identical.

The holes each have one of a circle, a hexagon, an octagon, and a combination of circle, hexagon, and octagon shape.

An exemplary embodiment of the present invention also discloses a method for fabricating a single-crystal GaN substrate, the method including forming an epitaxial growth heterogeneous substrate including forming a buffer layer including a plurality of layers disposed on a substrate, forming a plurality of holes penetrating the buffer layer and extending to the substrate, growing a single-crystal layer on the epitaxial growth heterogeneous substrate, and removing the substrate.

The buffer layer includes a first layer made of AlN disposed on the substrate, a second layer made of AlₓGa₁₋ₓN disposed on the first layer, wherein 0<x<1, and a third layer made of GaN disposed on the second layer, wherein the buffer layer is formed in a Metal Organic Vapor Phase Epitaxy (MOVPE) reaction chamber under a vacuum pressure of 500 torr.

The second layer is formed by gradually reducing ‘x’ in AlₓGa₁₋ₓN in a direction extending away from the first layer.

The second layer includes a plurality of layers having different Al compositions.

Forming a plurality of holes includes forming photoresist masks having uniform sizes and intervals on the buffer layer, forming hole regions penetrating the buffer layer by etching the buffer layer according to patterns formed by the photoresist masks, and forming undercut regions by etching part of the substrate, the undercut regions extending from the hole regions, wherein each of the undercut regions has a larger diameter than the hole region.

The hole regions are formed by dry etching, and the undercut regions are formed by dry etching or wet etching.

Each hole has a diameter in a range of 5 μm to 20 μm, and an interval between adjacent holes is in a range of 5 μm to 20 μm.

The single-crystal layer is made of an n-type or p-type GaN layer.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the present invention.

FIG. 1 is a perspective view illustrating an epitaxial growth heterogeneous substrate in accordance with an exemplary embodiment of the present invention.

FIGS. 2A and 2B are cross-sectional views illustrating the epitaxial growth heterogeneous substrate in accordance with an exemplary embodiment of the present invention.

FIGS. 3A and 3B are plan views illustrating holes for preventing a crack and easily detaching a heterogeneous substrate in the epitaxial growth heterogeneous substrate in accordance with an exemplary embodiment of the present invention.

FIGS. 4A, 4B, 4C, 4D, and 4E are diagrams showing a method for fabricating a single-crystal substrate using an epitaxial growth heterogeneous substrate in accordance with an exemplary embodiment of the present invention.

### DETAILED DESCRIPTION OF THE ILLUSTRATED EMBODIMENTS

Exemplary embodiments of the present invention will be described below in more detail with reference to the accompanying drawings. The present invention may, however, be embodied in different forms and should not be construed as limited to the embodiments set forth herein. Rather, these exemplary embodiments are provided so that this disclosure will be thorough and complete, and will fully convey the scope of the present invention to those skilled in the art. Throughout the disclosure, like reference numerals refer to like parts throughout the various figures and exemplary embodiments of the present invention.

The drawings are not necessarily to scale and in some instances, proportions may have been exaggerated in order to clearly illustrate features of the exemplary embodiments. When a first layer is referred to as being “on” a second layer or “on” a substrate, it not only refers to a case where the first layer is formed directly on the second layer or the substrate but also a case where a third layer exists between the first layer and the second layer or the substrate.

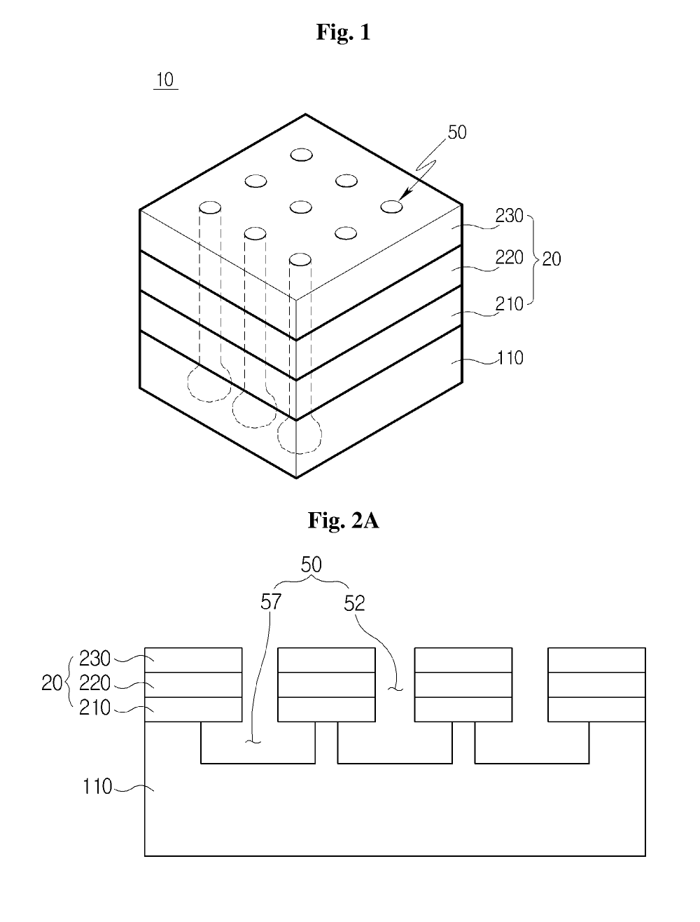

First, an epitaxial growth heterogeneous substrate in accordance with exemplary embodiments of the present invention is described with reference to FIGS. 1, 2A, 2B, 3A, and 3B.

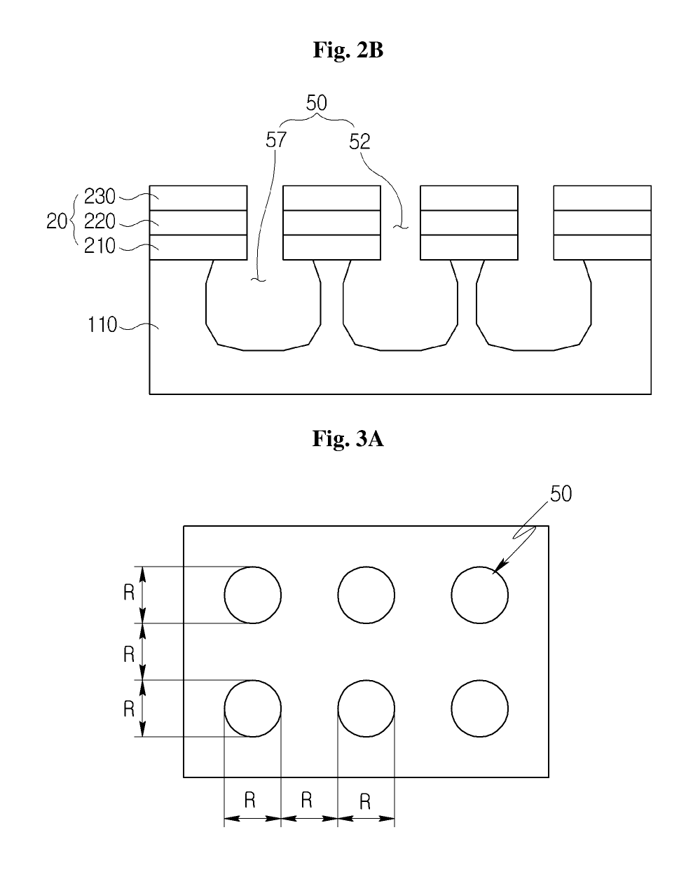

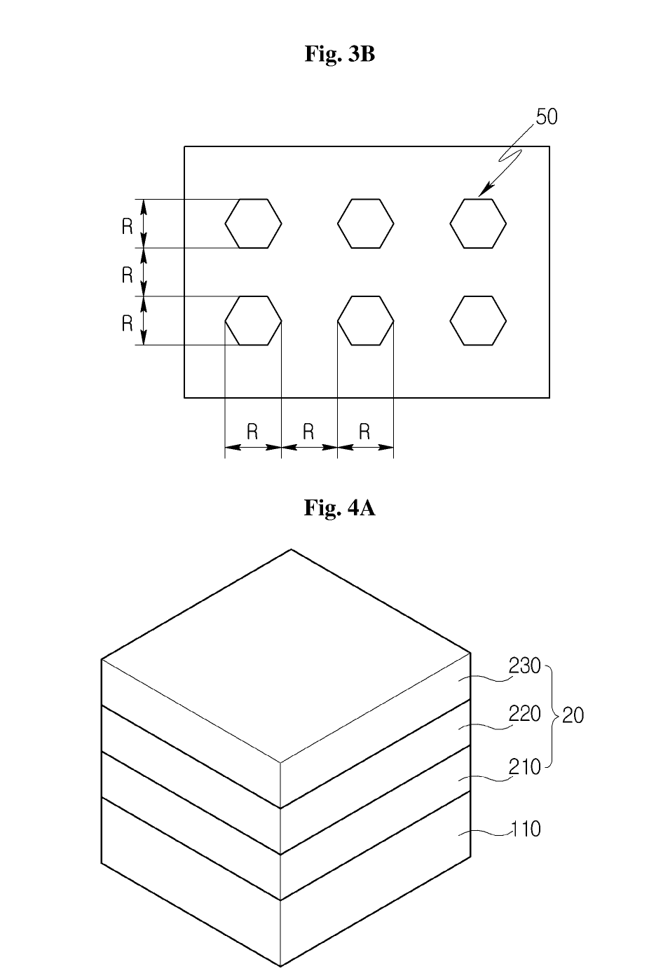

FIG. 1 is a perspective view illustrating an epitaxial growth heterogeneous substrate in accordance with an exemplary embodiment of the present invention, FIGS. 2A and 2B are cross-sectional views illustrating the epitaxial growth heterogeneous substrate in accordance with the present exemplary embodiment, and FIGS. 3A and 3B are plan views illustrating holes for preventing a crack and for detaching a heterogeneous substrate in the epitaxial growth heterogeneous substrate in accordance with an exemplary embodiment of the present invention.

Referring to FIG. 1, the epitaxial growth heterogeneous substrate 10 for single-crystal growth in accordance with an exemplary embodiment of the present invention includes a buffer layer 20 having a plurality of layers formed on a substrate 110. The buffer layer 20 has a first layer 210, a second layer 220, and a third layer 230 sequentially stacked thereon. Crack prevention holes 50 are disposed to have uniform sizes and intervals, and are formed in the buffer layer 20 and the substrate 110.

The epitaxial growth heterogeneous substrate 10 is a growth substrate which may be epitaxially grown. According to the present exemplary embodiment a silicon substrate 110 is used, but a sapphire substrate, an AlN substrate, or a SiC substrate may alternatively be used as the substrate 110. If a sapphire substrate is used, an undercut region may be formed between the sapphire substrate and a buffer layer disposed at the interface between heterogeneous substrates because part of the sapphire substrate is etched and the buffer layer is etched, due to difficult etching.

The buffer layer 20 may accelerate lateral growth of a subsequently grown semiconductor layer by reducing an interface energy with the grown semiconductor layer, thus the grown semiconductor layer may be capable of achieving planar growth. If the buffer layer 20 is not present, a three-dimensional rough surface may occur on a subsequently grown semiconductor layer because nucleation density is low and lateral growth fails to regularly occur. Furthermore, single-crystal growth may be achieved and a minute crack can be prevented when growing the buffer layer 20 on a heterogeneous substrate.

In order to facilitate the plane growth of a semiconductor layer grown on the substrate 110, the buffer layer 20 having a plurality of layers is grown on the substrate 110. The buffer layer may be a single layer in another exemplary embodiment.

The first layer 210, the second layer 220, and the third layer 230 are sequentially grown in the buffer layer 20 formed on the substrate 110.

In the absence of a buffer layer, a defect may be transferred due to a difference in the lattice constant between the substrate 110 and a GaN-based semiconductor layer grown thereon. The potential defect may generate strain and a difference in the thermal expansion coefficient. As a result, the defect may affect the growth of a single-crystal substrate, leading to a defective device and a low yield when fabricating the device using the single-crystal substrate. Accordingly, the buffer layer 20 is formed on the substrate 110, which may minimize the defect.

The first layer 210 of the buffer layer 20 contacts a surface of the substrate 110, and the first layer 210 may be an AlN-based material. The first layer 210 is formed to reduce the strain of the substrate 110. Accordingly, lattices are transferred to semiconductor layers formed on the first layer 210, thereby the first layer 210 is capable of reducing strain. The first layer 210 may have a thickness of 5 μm or less.

Next, the second layer 220 based on AlGaN is grown on the first layer 210. If a GaN layer is directly grown on the first layer 210 grown on the substrate 110, a crack may be generated between a high-growth temperature AlN layer and a high-growth temperature GaN layer due to strain. In order to avoid such a problem, the second layer 220 formed of an AlₓGa₁₋ₓN layer (0<x<1) having a multi-layer structure is grown between the first layer 210 and the GaN layer.

The second layer 220 may be grown by slowly changing an aluminum (Al) composition from X=1 to 0 during formation of the second layer 220. For example, several layers having different Al compositions may be grown. In the growth of the second layer 220 made of AlₓGa₁₋ₓN, an interface that neighbors the first layer 210 has a high Al composition, and the second layer 220 is formed so that the Al composition decreases as the second layer 220 is grown. The second layer 220 may have a thickness of 5 μm or less.

Next, the third layer 230 made of GaN-based materials is grown on the second layer 220. If GaN-based materials are grown on the buffer layer including the first layer 210 and the second layer 220, high-density nucleation is made possible because an interface energy is reduced as compared with a case where a thick and single-crystal GaN layer is directly grown on the substrate 110.

After nucleation, the third layer 230 made of GaN-based materials may be grown in a hexagonal pillar shape, such as a crystal shape, when the third layer 230 is initially grown. Furthermore, as GaN continues to be grown, adjacent hexagonal pillars are merged due to the acceleration of lateral growth which is attributable to a reduction of interface energy due to the buffer layer. Accordingly, the third layer 230 made of GaN-based materials has uniform plane growth due to the buffer layer. If the buffer layer is not present, however, the third layer 230 may have a low nucleation density and a three-dimensional rough surface because lateral growth fails to regularly occur.

As described above, a high-quality and single-crystal GaN-based substrate can be formed on the buffer layer 20 because interface energy is reduced, nucleation is facilitated, and plane growth having a uniform growth surface is facilitated due to the buffer layer 20 formed of the plurality of layers 210, 220, and 230.

The epitaxial growth heterogeneous substrate 10 in accordance with exemplary embodiments of the present invention includes the crack prevention holes 50 disposed in the substrate 110 and the buffer layer 20 at uniform intervals and in a uniform form. The crack prevention holes 50 are formed in part of the substrate 110 through the buffer layer 20 formed of the plurality of layers.

Referring to FIGS. 2A and 2B, the crack prevention holes 50 include hole regions 52 configured to penetrate the buffer layer 20 and undercut regions 57 extended from the hole regions 52 and configured to etch part of the substrate 110. The hole regions 52 and the undercut regions 57 of the crack prevention holes 50 may be formed by wet or dry etching.

First, the undercut regions 57 can be undercut in order to reduce a contact area between the substrate 110 and the buffer layer 20. Here, strain may be generated in the first layer 210 and the substrate 110 because the substrate 110 and the buffer layer 20 have different lattice constants and different thermal expansion coefficients. The first layer 210 and the substrate 110 may have a difference in the thermal expansion coefficient and the lattice constant because they are made of heterogeneous materials. When growing a thick-film single-crystal GaN layer, strain may be generated between the substrate 110 and the first layer 210. Accordingly, the strain can be reduced by forming the undercut region 57 in order to reduce the contact area in a region in which strain may be generated.

As described above, the undercut region 57 may have a larger diameter than the hole region 52. The undercut region 57 of the crack prevention hole 50 may have a shape formed by etching part of the substrate 110 other than the hole region 52 through control of etching conditions, as shown in FIG. 2A. In another exemplary embodiment, the hole region 52 may have a round sectional shape formed by etching part of the substrate 110, as shown in FIG. 2B.

The crack prevention hole 50 includes the hole region 52 extended to the undercut region 57 and configured to penetrate the buffer layer 20. The epitaxial growth heterogeneous substrate 10 may be formed by forming the buffer layer 20 including the crack prevention holes 50 including the hole regions 52.

Here, a single-crystal substrate formed of a single-crystal layer may be formed by growing the single-crystal layer on the buffer layer 20, particularly, a surface contacting the hole regions 52 exposed from the top surface of the buffer layer 20, and then separating the epitaxial growth heterogeneous substrate 10. The single-crystal layer may be used as one single-crystal substrate or may be cut and used as a plurality of single-crystal substrates.

Referring to FIGS. 2A and 2B, the substrate 110 and the buffer layer 20 may have strain due to lattice mismatch, and the strain may be transferred to a single-crystal layer that is subsequently formed on the buffer layer 20. The strain transferred to the single-crystal layer may cause the substrate 110 and a single-crystal substrate to break when forming the single-crystal substrate.

Thus, the hole regions 52 minimizing a contact area with the single-crystal layer formed on the buffer layer 20 are provided in the crack prevention holes 50 formed in the epitaxial growth heterogeneous substrate 10 in accordance with an exemplary embodiment of the present invention in order to prevent a crack generated due to strain from being transferred to the single-crystal layer.

FIGS. 3A and 3B show the arrangement of the crack prevention holes 50 seen from the top of the buffer layer 20. FIGS. 3A and 3B illustrate the size and arrangement of the hole regions 52.

The hole regions 52 of the crack prevention holes 50 may have uniform diameters and intervals, and the hole regions 52 may be uniformly disposed. The hole regions 52 may have a uniform size R and a uniform interval R. This is because if the hole regions 52 lean in any one direction (that is, if the interval R is not uniform), strain may be concentrated on a region in which a relatively small number of the hole regions 52 are disposed, leading to a crack.

Each of the crack prevention holes 50 may have a circle having a diameter of 5 μm to 20 μm. In another exemplary embodiment, the crack prevention hole 50 may have a hexagon or an octagon shape. Furthermore, the interval between adjacent crack prevention holes 50 may be 5 μm to 20 μm.

By forming the crack prevention holes 50 in a uniform size at uniform intervals as described above, strain transferred to the single crystal layer formed on the buffer layer 20 can be minimized because any strain that may occur may be uniformly distributed. Accordingly, the epitaxial growth heterogeneous substrate 10 in accordance with the present exemplary embodiment may improve the yield and achieve a large size (i.e., a large diameter) of a single-crystal substrate grown thereon by preventing the single-crystal substrate from being broken due to a crack when growing the single-crystal substrate.

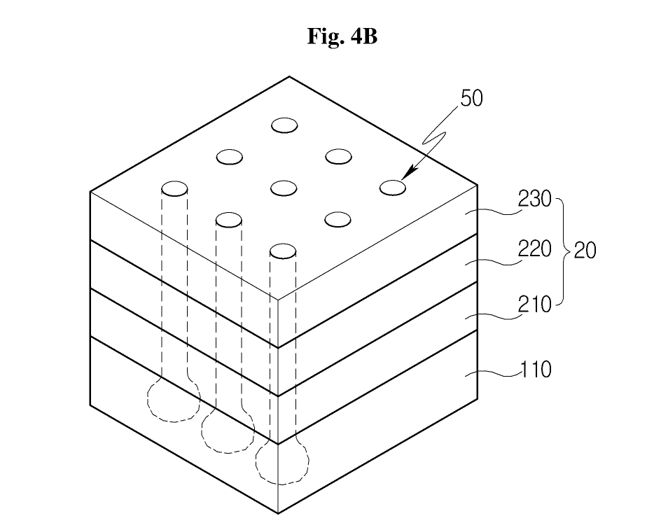

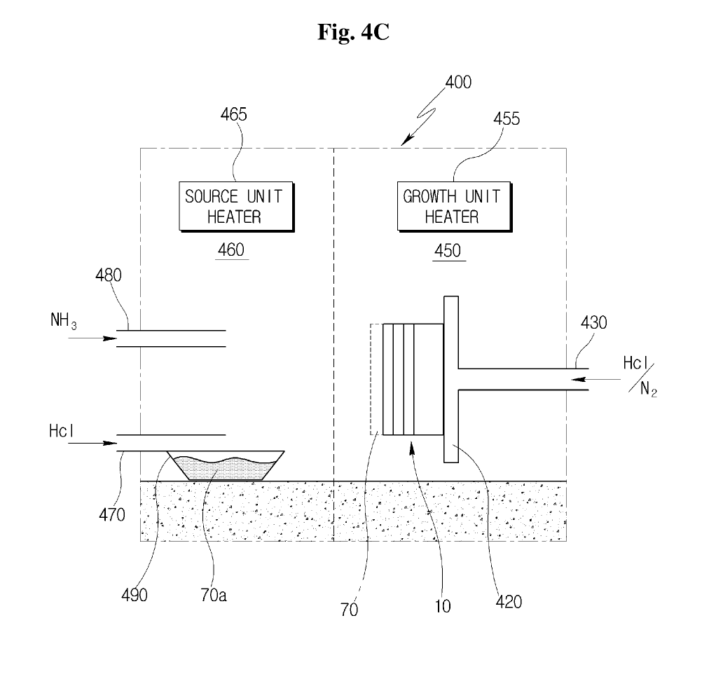

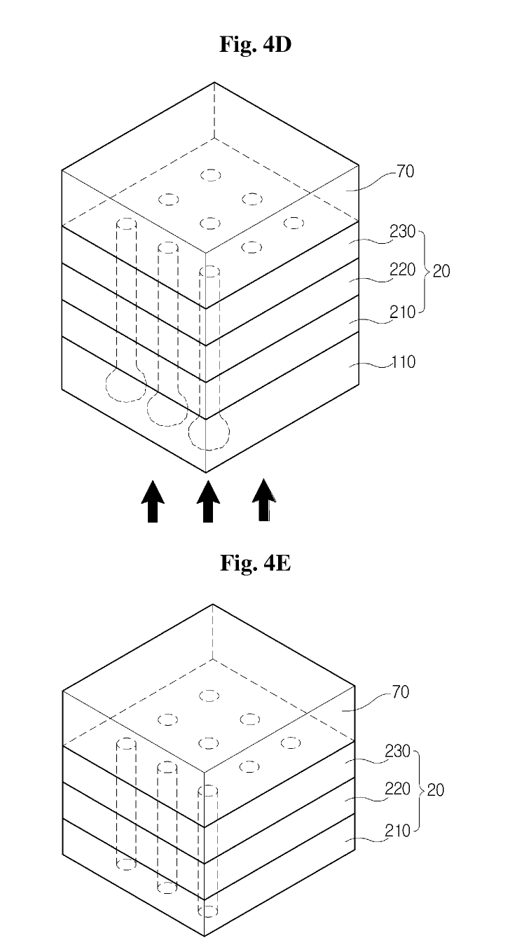

FIGS. 4A, 4B, 4C, 4D, and 4E are diagrams showing a method for fabricating a single-crystal substrate using an epitaxial growth heterogeneous substrate in accordance with an exemplary embodiment of the present invention. Growth of a nitride-based single-crystal substrate is described in the present exemplary embodiment.

First, in order to form a single-crystal substrate, an epitaxial growth heterogeneous substrate 10 including a substrate 110, a buffer layer 20, and crack prevention holes 50 is formed. The epitaxial growth heterogeneous substrate 10 is described with reference to FIGS. 1, 2A, 2B, 3A, and 3B.

As shown in FIG. 4A, the buffer layer 20 including a first layer 210 formed of a thin film AlN layer, a second layer 220 formed of an AlₓGa₁₋ₓN (0<x<1) layer having a multi-layer structure, and a third layer 230 formed of GaN is formed on the substrate 110 using Metal Organic Vapor Phase Epitaxy (MOVPE).

An Si substrate may be used as the substrate 110 if a semiconductor can be grown thereon. The Si substrate can be used as a plane (111). If other than the plane (111) of the Si substrate is used, polycrystals not a single-crystal may be grown on the Si substrate. If a GaN layer including the AlN layer is grown on the substrate 110 based on the (111)-plane Si substrate, planar growth may be achieved. In order to grow a semipolar or nonpolar plane, however, a surface of the substrate may be other than the (111)-plane, and the growth of the surface may be controlled by using SiO₂, and lateral growth may be accelerated.

Next, the buffer layer 20 formed of the plurality of layers is formed on the substrate 110. In order to form the multi-layer buffer layer 20, the substrate 110 is placed in an MOVPE reaction chamber, vacuum within the MOVPE reaction chamber is decreased to about 500 torr, and temperature within the MOVPE reaction chamber is raised to 1000° C. to 1200° C. Next, when a trimethyl aluminum (TMA) source and NH₃ gas as a carrier gas are flowed into the MOVPE reaction chamber, the first layer 210 made of high-growth temperature AlN is grown on the substrate 110. AlN may be grown in a temperature range of 1200° C. to 1500° C. because crystallinity may be improved according to a temperature increase. If the AlN layer is directly grown over 1200° C. when growing the AlN layer on the Si substrate, however, a surface of the Si substrate may be thermally decomposed. In order to prevent this problem, the AlN layer may be grown on the Si substrate by controlling temperature when the AlN layer is initially grown on a surface of the Si substrate.

In order to reduce strain and grow the GaN layer under such a condition, the first layer 210 based on initial high-growth temperature AlN is grown on the substrate 110.

The buffer layer 20 may be grown based on low-growth temperature AlN at about 600° C. If the buffer layer 20 is grown based on low-temperature AlN at about 600° C., however, the crystallinity of the GaN layer included in the buffer layer 20 may be deteriorated. Accordingly, a high-growth temperature AlN layer may be used. Alternatively, a method using both low temperature and high temperature may be used.

The first layer 210 may have a thickness of 3 μm to 7 μm or less. The first layer 210 has a thickness of 5 μm or less in order to facilitate an etching process for forming the crack prevention holes 50.

If a GaN layer is directly grown on the first layer 210, a crack may be generated due to strain between the high-growth temperature first layer 210 and the high-growth temperature third layer 230.

In order to prevent such a crack, the second layer 220 formed of AlₓGa₁₋ₓN having a multi-layer structure may be grown between the first layer 210 and the third layer 230. The second layer 220 may be grown in a temperature range of 1000° C. to 1200° C. The second layer 220 formed of AlₓGa₁₋ₓN having a multi-layer structure may be grown by slowly changing an Al composition from X=1 to 0, or several layers having different Al compositions may be grown.

A basic factor in growing the AlₓGa₁₋ₓN layer is by lowering the Al composition in a surface that comes in contact with the third layer 230 while raising the Al composition in a region that comes in contact with the first layer 210.

The second layer 220 may have a thickness of 0.1 μm to 2 μm or less. The third layer 230 made of GaN is grown on the second layer 220 formed of AlₓGa₁₋ₓN as described above. Here, the third layer 230 may be continuously grown under the same temperature conditions as the second layer 220. The third layer 230 may have a growth thickness of 0.1 μm to 2 μm or less.

As shown in FIG. 4B, the crack prevention holes 50 are formed in the buffer layer 20. Although not shown, photoresist (PR) masks corresponding to the shapes of the crack prevention holes 50 are formed through PR coating in the state in which the buffer layer 20 has been formed on the substrate 110, and the buffer layer 20 and the substrate 110 are etched.

The third layer 230 formed of GaN, the second layer 220 formed of AlₓGa₁₋ₓN having a multi-layer structure, and the first layer 210 formed of AlN may be subject to dry etching using Inductively Coupled Plasma-Reactive Ion Etching (ICPRIE), for example. In order to etch the buffer layer 20, Cl₂ gas may be used as an etching gas.

Furthermore, an etching process using a dry etching method may be performed on the substrate 110. Here, SF₆ may be used as an etching gas. As described above, the crack prevention holes 50 may be formed through a dry etching process.

The substrate 110 may be etched in an undercut form in order to minimize strain occurring due to a difference between the lattice constants of the first layer 210 and the substrate 110 when growing thick and single-crystal GaN thereon. Regions in which the substrate 110 has been subject to undercut etching as described above are defined as the undercut regions 57. In order to implement the undercut regions 57, the etching process may be performed by controlling conditions, such as an etching time or an etching solution.

The etching process for the substrate 110 and the buffer layer 20 is not limited to the dry etching process as described, but conditions for the etching process may be changed or both dry etching and wet etching may be used. Furthermore, KOH may be used as the etching solution used in the wet etching process. In addition, solutions based on OH⁻ may be used as the etching solution used in the wet etching process.

The crack prevention holes 50 may be formed to have uniform sizes and uniform intervals. Furthermore, the crack prevention holes 50 may have the same size R and interval R. The crack prevention holes 50 are described with reference to FIGS. 3A and 3B above, in order to avoid a redundant description.

By providing the epitaxial growth heterogeneous substrate 10 in which the crack prevention holes 50 having a uniform size have been disposed as described above, strain that may occur when growing a thick and single-crystal GaN layer grown thereon can be minimized because a contact area between the substrate 110 and the buffer layer 20 is reduced. Furthermore, a single-crystal layer having high quality and a large area (or a large diameter) can be formed on the buffer layer 20 because a layer formed on the epitaxial growth heterogeneous substrate 10 also has a reduced contact area of an interface subject to strain.

As shown in FIGS. 4C and 4D, a single-crystal layer 70 is formed on the epitaxial growth heterogeneous substrate 10. The crack prevention holes 50 may reduce a contact area between the epitaxial growth heterogeneous substrate 10 and the single-crystal layer 70.

The single-crystal layer 70 may be formed using a Hydride Vapor Phase Epitaxy (HVPE) method. An exemplary embodiment in which a GaN layer is grown as the single-crystal layer 70 is described below. The crack prevention holes 50 are formed in the buffer layer 20 grown on the substrate 110, and the epitaxial growth heterogeneous substrate 10 is disposed in the growth unit 450 of an HVPE reaction chamber 400. Particularly, the epitaxial growth heterogeneous substrate 10 is placed in a susceptor 420.

The HVPE reaction chamber 400 may be divided into two parts. The two parts include a source unit 460 in which metal gallium (Ga) 70a heated to about 800° C. is disposed and a source unit heater 465 is disposed, and the growth unit 450 in which the epitaxial growth heterogeneous substrate 10 heated to about 1100° C. is disposed, a thick single-crystal layer 70 is grown, and a growth unit heater 455 is disposed.

After the epitaxial growth heterogeneous substrate 10 is disposed in the growth unit 450, an H₂/N₂ atmosphere is formed within the HVPE reaction chamber 400 by removing impurity gases, such as oxygen, within the HVPE reaction chamber 400 using N₂ gas or H₂ gas. The impurity gases, such as oxygen, may be removed using a vacuum pump.

GaCl can be formed by slowly raising the temperature within the HVPE reaction chamber 400 using the heater units 450 and 460 and then flowing HCl gas on a surface of the metal Ga 70a through a first source tube 470. Here, a large amount of gallium (Ga) can be supplied to the epitaxial growth heterogeneous substrate 10 because GaCl is easily decomposed into gallium (Ga) by heat. Furthermore, NH₃ gas may be additionally flowed through a second source tube 480 in order to supply nitrogen (N), so that the single-crystal layer 70 made of GaN may be formed by a reaction of gallium (Ga) and nitrogen (N). Here, the single-crystal layer 70 may be grown in a temperature range of 1000° C. to 1200° C. In general, the single-crystal layer 70 has an n-type characteristic although it is not doped, but may be arbitrarily grown into an n-type through Si doping or may be arbitrarily grown into a p-type through Mg doping.

The single-crystal layer 70 made of GaN may be grown on the third layer 230 by supplying nitrogen (N) gas, decomposed in Ga and NH₃ as described above, to the epitaxial growth heterogeneous substrate 10. Here, the grown single-crystal layer 70 may have a thickness of 300 mm to 1 mm. Furthermore, the single-crystal layer 70 may be grown to have a thickness of several mm through single-crystal growth and then cut into several sheets of single-crystal substrates.

Furthermore, the epitaxial growth heterogeneous substrate 10 may be disposed in the growth unit 450, and the temperature within the HVPE reaction chamber 400 may be raised. The susceptor 420 in which the epitaxial growth heterogeneous substrate 10 is disposed may be externally taken out or internally put in the state in which temperature within the HVPE reaction chamber 400 has risen.

Meanwhile, a nozzle unit 430 is connected to the susceptor 420. HCl gas is supplied to the back of the epitaxial growth heterogeneous substrate 10 through the nozzle unit 430 at a high temperature. Thus, the GaN layer may be prevented from being deposited on the back side of the substrate 110.

Carrier gas, such as nitrogen (N) or hydrogen (H), in addition to HCl gas can also be supplied through the nozzle unit 430. Accordingly, the rotation of the substrate may be controlled. If the substrate is rotated, the thickness uniformity of a grown GaN layer may be improved and the GaN layer may be controlled so that it is not deposited on the back side of the substrate 110. Furthermore, since the substrate 110 can be etched by HCl gas supplied through the nozzle unit 430, the substrate 110 disposed at the bottom of the susceptor 420 may be etched due to a small amount of HCl gas while growing the single-crystal layer 70 if a small amount of HCl gas is made to flow through part of the susceptor 420. The entire substrate may be uniformly removed while rotating the substrate.

As shown in FIG. 4D, after growing the single-crystal layer 70 through the HVPE reaction chamber 400, a void layer 90 may be formed in an interface region in which the bottom surface of the single crystal layer 70 comes in contact with the top surface of the crack prevention holes 50. The void layer 90 may be formed in the case where growth speed is fast and growth temperature is high when growing the single crystal layer 70 in the HVPE reaction chamber 400.

As shown in FIG. 4E, the substrate 110 may be etched by HCl gas while growing the single crystal layer 70, or only the substrate 110 may be etched using an etching solution, such as KOH.

If the substrate 110 is removed as described above, only the buffer layer 20 and the single crystal layer 70 remain. Here, only the single crystal layer 70 may remain if the buffer layer 20 is further etched.

In another exemplary embodiment, the single-crystal substrate may be fabricated by performing surface processing using polishing on the buffer layer 20 and the single-crystal layer 70.

Here, if processing damage attributable to polishing is not fully removed, it may be removed by dry etching for use as a single-crystal substrate.

When the substrate 110 is removed using an etching method as described above, the fabrication yield of a single-crystal substrate may be improved because a crack occurring due to the temporal weakening of strain is prevented.

In accordance with exemplary embodiments of the present invention, a contact area between the epitaxial growth heterogeneous substrate and the single-crystal layer can be reduced because the epitaxial growth heterogeneous substrate includes the crack prevention holes. Accordingly, a crack and bending can be prevented and a wide area (or a large diameter) can be achieved.

In accordance with other exemplary embodiments of the present invention, the method for fabricating a single-crystal GaN substrate using an epitaxial growth heterogeneous substrate may improve the yield thereof by reducing a phenomenon in which the substrate and the single-crystal layer are damaged due to the temporal weakening of strain because the substrate is detached using an etching method.

While the present invention has been described with respect to the specific exemplary embodiments, it will be apparent to those skilled in the art that various changes and modifications may be made without departing from the spirit and scope of the invention as defined in the following claims.

What is claimed is:

1. A single-crystal GaN substrate, comprising:
a buffer layer comprising a nitride semiconductor;
holes penetrating the buffer layer; and
a single-crystal nitride semiconductor disposed on the buffer layer.

2. The single-crystal GaN substrate of claim 1, wherein the buffer layer comprises:
a first layer disposed on the substrate, the first layer comprising AlN;
a second layer disposed on the first layer, the second layer comprising AlₓGa₁₋ₓN, wherein 0<x<1; and
a third layer disposed on the second layer, the third layer comprising GaN.

3. The single-crystal GaN substrate of claim 1, further comprising a substrate, wherein the buffer layer is disposed on the substrate, and the holes extend into the substrate.

4. The single-crystal GaN substrate of claim 3, wherein each of the holes comprises a hole region penetrating the buffer layer and an undercut region extending from the hole region and etching part of the substrate, and
wherein the undercut region has a larger diameter than the hole region.

5. The single-crystal GaN substrate of claim 2, wherein the second layer comprises gradually reduced ‘x’ in AlₓGa₁₋ₓN in a direction extending away from the first layer.

6. The single-crystal GaN substrate of claim 2, wherein the second layer comprises layers comprising different Al compositions and a gradually reduced composition of ‘x’ in a direction extending away from the first layer.

7. The single-crystal GaN substrate of claim 1, wherein the holes comprise uniform diameters and intervals therebetween.

8. The single-crystal GaN substrate of claim 1, wherein an interval between adjacent holes is identical.

9. The single-crystal GaN substrate of claim 1, wherein the holes each comprise one of a circle, a hexagon, an octagon, and a combination of the circle, the hexagon, and the octagon shape.

10. A method for fabricating a single-crystal GaN substrate, the method comprising:
forming an epitaxial growth heterogeneous substrate, comprising:
forming a buffer layer comprising a plurality of layers disposed on a substrate; and
forming a plurality of holes penetrating the buffer layer and extending to the substrate;
growing a single-crystal layer on the epitaxial growth heterogeneous substrate; and
removing the substrate.

11. The method of claim 10, wherein the buffer layer comprises:
a first layer comprising AlN disposed on the substrate;
a second layer comprising AlₓGa₁₋ₓN disposed on the first layer, wherein 0<x<1; and
a third layer comprising GaN disposed on the second layer,
wherein the buffer layer is formed in a Metal Organic Vapor Phase Epitaxy (MOVPE) reaction chamber under a vacuum pressure of 500 torr.

12. The method of claim 11, wherein the second layer is formed by gradually reducing ‘x’ in AlₓGa₁₋ₓN in a direction extending away from the first layer.

13. The method of claim 11, wherein the second layer comprises a plurality of layers comprising different Al compositions.

14. The method of claim 10, wherein forming the plurality of holes comprises:
forming photoresist masks comprising uniform sizes and intervals on the buffer layer;
forming hole regions penetrating the buffer layer by etching the buffer layer according to patterns formed by the photoresist masks; and
forming undercut regions by etching part of the substrate, the undercut regions extending from the hole regions,
wherein each of the undercut regions has a larger diameter than the hole region.

15. The method of claim 14, wherein:
the hole regions are formed by dry etching, and
the undercut regions are formed by dry etching or wet etching.

16. The method of claim 10, wherein:
each hole has a diameter in a range of 5 μm to 20 μm, and
an interval between adjacent holes is in a range of 5 μm to 20 μm.

17. The method of claim 10, wherein the single-crystal layer comprises an n-type or p-type GaN layer.
